(19) United States
(12) Patent Application Publication
(10) Pub. No.: US 2009/0315554 A1
(43) Pub. Date: Dec. 24, 2009

(54) INTEGRATED THREE-DIMENSIONAL MAGNETIC SENSING DEVICE AND METHOD TO FABRICATE AN INTEGRATED THREE-DIMENSIONAL MAGNETIC SENSING DEVICE

(75) Inventors: William Witcraft, Minnetonka, MN (US); Thomas Keyser, Plymouth, MN (US); Thomas Ohnstein, Roseville, MN (US)

Correspondence Address: HONEYWELL INTERNATIONAL INC.;PATENT SERVICES AB-2B, 101 COLUMBIA ROAD, P.O. BOX 2245, MORRISTOWN, NJ, 07962-2245, US

(73) Assignee: HONEYWELL INTERNATIONAL INC., Morristown, NJ (US)

(21) Appl. No.: 12/143,380

(22) Filed: Jun. 20, 2008

(51) Int. Cl. G01R 33/02

(52) U.S. Cl. 324/260

(57) ABSTRACT

A three-axis magnetic sensing device included on a single chip. An example three-axis magnetic sensing device includes first and second sensing components that sense magnetic fields along two orthogonal axes planar to a surface of a substrate and a third sensing component that senses a magnetic field along an axis out of plane of the surface of the substrate. The third sensing component includes a carbon-based material. In one example, the first and second sensing components are anisotropic magnetoresistive sensors. In another example, the carbon-based material includes carbon nanotubes and the third sensing component includes a needle attached to the carbon-based material and electrodes that make contact with the carbon-based material.

### BACKGROUND OF THE INVENTION

Magnetic sensing devices facilitate the measurement of a magnetic field (i.e., one or more magnetic fields) for a variety of applications by using one or more magnetic sensor units to sense the magnetic field, and to provide output signals that represent the magnetic field. Navigation applications that determine a heading determination are popular applications for magnetic sensing devices. A heading determination may indicate a direction, such as North or Northeast. Other applications for magnetic sensing devices, such as proximity detection, are also possible.

The one or more magnetic sensor units in a magnetic sensing device may be arranged in a manner that provides sensing of particular components of a magnetic field. For example, a first magnetic sensor unit may be arranged to sense a component of a magnetic field in a direction defined as the x-axis direction, and a second magnetic sensor unit may be arranged to sense a component of the magnetic field in a direction defined as the y-axis direction. In this example, the magnetic sensing device could provide an output signal that represents components of the magnetic field in the x-axis direction and an output signal that represents components of the magnetic field in the y-axis direction.

A wide variety of magnetic sensor unit types are available such as reed switches, variable reluctance sensors, flux-gate magnetometers, magneto-inductor sensors, spin-tunnel device sensors and Hall-Effect sensors. Another magnetic sensor unit type is a magnetic sensor unit that comprises magnetoresistive material. Examples of magnetic sensors comprising magnetoresistive material include giant magneto-resistive sensors and giant magneto-impedance sensors. Other examples are also possible.

Magnetoresistive material is a material with a variable resistance value that varies depending in part on a magnetic field in proximity to the magnetoresistive material. The sensitivity of magnetoresistive material to change its resistance value when exposed to a magnetic field depends in part on the characteristics of a particular magnetoresistive material. Common magnetoresistive materials include anisotropic magnetoresistive (AMR) two-axis materials and giant magnetoresistive (GMR) materials, which are both described in U.S. Pat. No. 5,569,544 and colossal magnetoresistive (CMR) materials described in U.S. Pat. No. 5,982,178. National Aeronautics and Space Administration (NASA) presents a NanoCompass technology at the following locationhttp://ipp.gsfc.nasa.gov/ft-tech-NanoCompass.html.

One type of AMR material is a nickel-iron material known as Permalloy. AMR-type magnetic sensor units may include thin films of Permalloy deposited on a silicon wafer and patterned as a resistor. Multiple resistors made of Permalloy may be coupled together to form an electrical circuit. The electrical circuit could take the form of a bridge configuration, such as a Wheatstone bridge.

During fabrication of AMR-type magnetic sensor units, the AMR magnetoresistive material is deposited on a silicon substrate in the presence of a strong magnetic field. This strong magnetic field sets a magnetization vector in the AMR magnetoresistive material resistor to be parallel to the length of the resistor by aligning the magnetic domains of the AMR magnetoresistive material in the same direction. Magnetic domains are clusters of atoms within the AMR magnetoresistive material with their magnetic moment pointing in the same direction.

Magnetic sensing devices are available in a variety of one-axis and two-axis configurations. The number of axes in a magnetic sensing device refers to the number of sensitive axes or sensing directions for measuring a magnetic field. Magnetic sensing devices with more than one axis typically arrange the multiple axes to be mutually orthogonal. However, there does not exist three axis sensors of this type.

### SUMMARY

The present invention provides a three-axis magnetic sensing device included on a single chip. An example three-axis magnetic sensing device includes first and second sensing components that sense magnetic fields along two orthogonal axes planar to a surface of a substrate and a third sensing component that senses a magnetic field along an axis out of plane of the surface of the substrate. The third sensing component includes a carbon-based material.

In one aspect of the present invention, the first and second sensing components are anisotropic magnetoresistive sensors and the carbon-based material includes carbon nanotubes. The third sensing component includes a needle attached to the carbon-based material and electrodes that make contact with the carbon-based material.

### BRIEF DESCRIPTION OF THE DRAWINGS

Preferred and alternative embodiments of the present invention are described in detail below with reference to the following drawings:

FIG. 1-1 illustrates a top view of a three-dimensional sensing device formed in accordance with an embodiment of the present invention;

FIG. 1-2 illustrates a side plan view of the sensing device shown in FIG. 1;

FIGS. 2-1 through 2-4 illustrate side views of a process for manufacturing a portion of the three-dimensional magnetic sensing device as shown in FIG. 1; and

FIG. 3 illustrates an example sensor package with circuit components included in another layer.

### DETAILED DESCRIPTION OF THE INVENTION

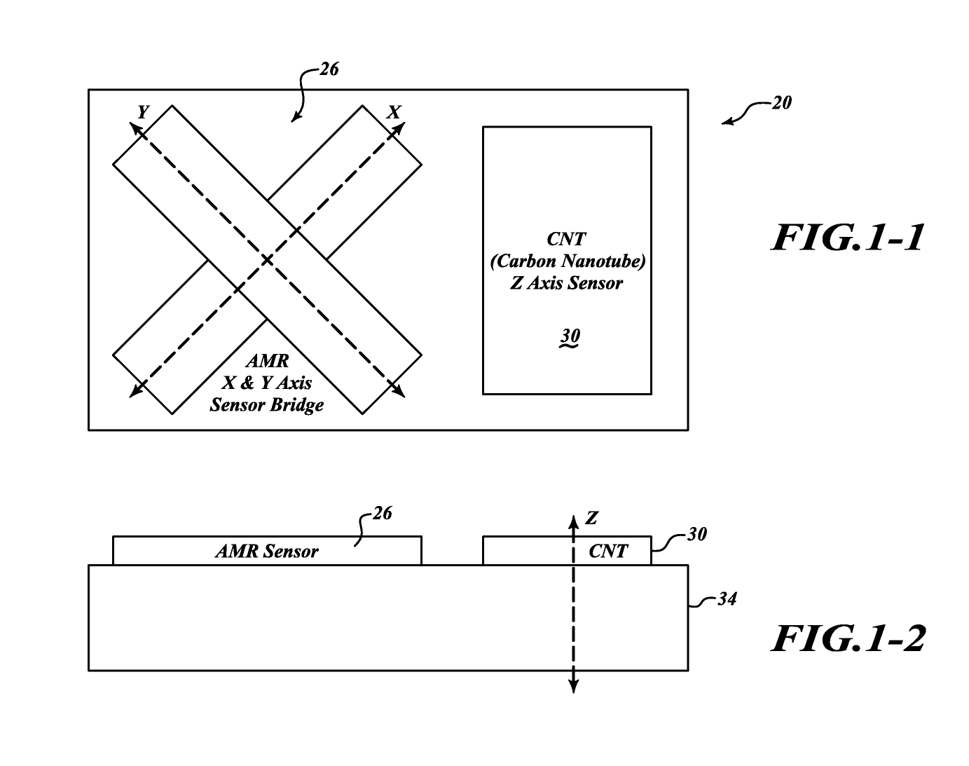

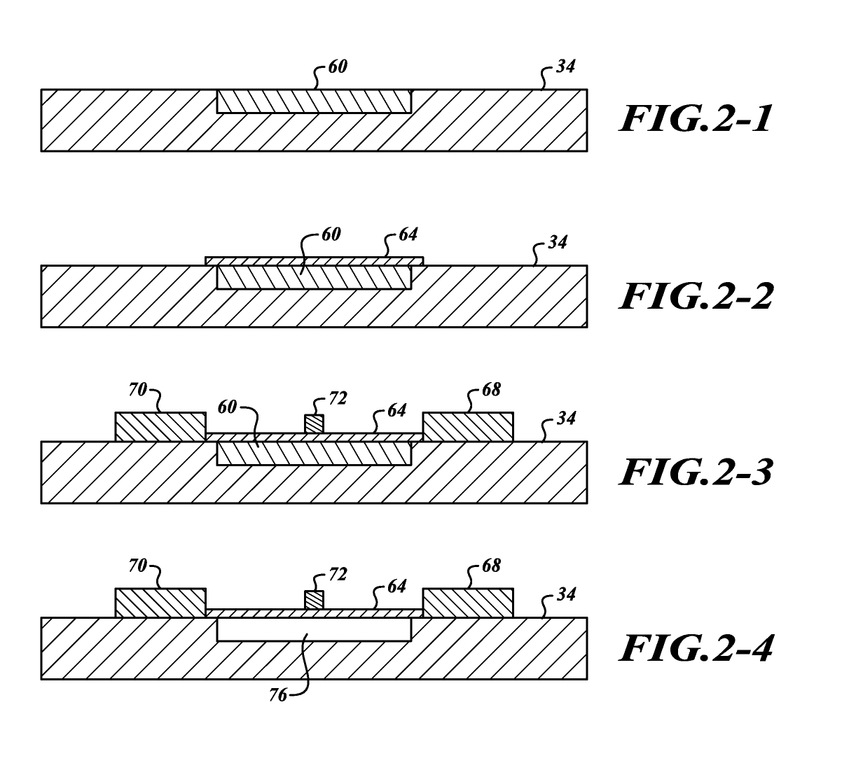

FIGS. 1-1 and 1-2 illustrate top and side views of an embodiment of an example integrated three-dimensional magnetic sensing device 20. The integrated three-dimensional magnetic sensing device 20 includes an anisotropic magnetoresistive (AMR) two-axis sensor 26 and a carbon nanotube (CNT) z-axis sensor 30. The AMR sensor 26 and the CNT sensor 30 are formed on a single substrate 34.

The single substrate 34 could be formed of silicon, germanium, glass, plastic, any combination or some other suitable material. Other layers (not shown) could include silicon, silicon dioxide (SiO₂), plastic or some other material for supporting the AMR sensor 26 and other circuit components.

The single substrate 34 may include more or fewer layers than those shown in FIGS. 1-2. Fibers or networks of material that exhibit a strain gauge effect which product a change in resistance when stressed are examples of a carbon nantotube network.

The AMR sensor 26 includes magnetoresistive material having a plurality of magnetoresistive strips and interconnections that couple the strips to form an electrical circuit. In one embodiment, the electrical circuit is formed as an X and Y-axis sensor bridge, such as a Wheatstone bridge configuration for each axis. Other configurations for the electrical circuit are possible.

The CNT sensor 30 includes a layer of carbon nanotubes for a free-standing network of single walled or multi walled carbon nanotubes that are suspended between electrodes and mechanically coupled to a magnetically responsive, high aspect-ratio, ferro-magnetic component (i.e. needle). An example needle includes iron (Fe). The CNT sensor 30 may also include other circuitry (not shown), such as voltage source, current amplifier and digital data acquisition component.

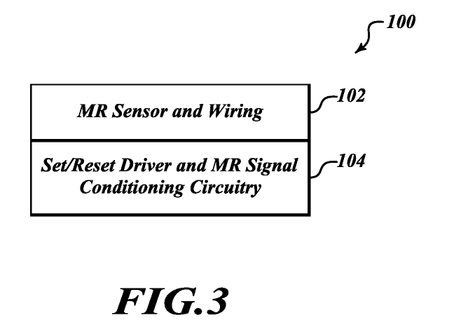

In one non-limiting embodiment, control and interfacing circuitry is formed on a silicon wafer or in a silicon layer. Then, elements of the AMR sensor 26 are deposited and patterned to form the X-axis and Y-axis magnetic sensing elements. Then, the elements of the CNT sensor 30 are formed, by the processes shown in FIGS. 2 and 3 below, for example. Additional interconnects may be formed in the device to connect to the AMR sensor 26 with any other circuit components. Also, the AMR sensor 26 and CNT sensor 30 may be formed on different layers and/or interconnected with additional layers.

FIGS. 2-1 through 2-4 illustrate a first example method for the creation of the CNT sensor 30. First, as shown in FIG. 2-1, a trench is patterned, etched and filled with a sacrificial material 60 (e.g., polyimide). Example sacrificial material 60 includes Cr or any other material that can be easily removed at a later time. Next, as shown in FIG. 2-2, a thin film of CNT material is spun onto the substrate 34 and then patterned into a desired pattern (CNT film 64). An example of CNT film product (carbon nanotube networks) is produced by Brewer Science, Inc. The CNT film 64 has a range between approximately 10 to 10000 Angstroms.

The CNT film 64 is patterned using known techniques over the sacrificial layer 60 such that it extends past at least two of the opposing walls that are surrounding the sacrificial layer 60. Next, as shown in FIG. 2-3, electrodes 68 and 70 are deposited onto the surface of the first layer 34 and patterned using known techniques (lift-off) so that they come in contact with opposing ends of the CNT film 64. The electrodes 68 and 70 could also be formed beforehand by embedding the conductors in a layer of the substrate below the ends of the to-be-formed CNT film 64.

Then, a needle 72 is deposited and patterned using known techniques on top of the CNT film 64 at approximately the center of the CNT film 64 between the two electrodes 68 and 70. Next, as shown in FIG. 2-4, the sacrificial layer 60 is etched using a known solvent, such as a wet solvent etch, for producing a cavity 76 that is located underneath a portion of the CNT film 64. Because the CNT film 64 is supported over the new cavity 76, the CNT film 64 remains at rest over the cavity 76. The electrodes 68 and 70 are then connected to other circuit components (not shown).

FIG. 3 shows general configuration 100 for the sensors described above located in a first layer 102 that is located on top of or adjacent to and fabricated on the same substrate as driver and conditioning circuitry located in a second layer 104. An example of such driver and conditioning circuitry (integrated silicon circuitry) is described in copending U.S. patent application Ser. No. 11/782,455 filed Jul. 24, 2007, the contents of which are hereby incorporated by reference.

While the preferred embodiment of the invention has been illustrated and described, as noted above, many changes can be made without departing from the spirit and scope of the invention. For example, the order in which fabrication steps are performed in FIGS. 2-1 through 2-4 may be altered without affecting the final design. Accordingly, the scope of the invention is not limited by the disclosure of the preferred embodiment. Instead, the invention should be determined entirely by reference to the claims that follow.

The embodiments of the invention in which an exclusive property or privilege is: claimed are defined as follows:

1. A three-axis magnetic sensing device comprising:
first and second sensing components configured to sense magnetic fields along two orthogonal axes planar to a surface of a substrate; and
a third sensing component configured to sense a magnetic field along an axis out of plane of the surface of the substrate,
wherein the third sensing component includes a carbon-based material.

2. The device of claim 1, wherein the first and second sensing components comprise anisotropic magnetoresistive sensors.

3. The device of claim 2, wherein the carbon-based material comprises carbon nanotubes.

4. The device of claim 3, wherein the third sensing component includes a needle attached to the carbon-based material.

5. The device of claim 4, wherein the needle comprises ferromagnetic material.

6. The device of claim 4, wherein the third sensing component further comprises at least two electrodes that make contact with the carbon-based material.

7. The device of claim 1, wherein the carbon-based material comprises carbon nanotubes.

8. The device of claim 1, wherein the third sensing component includes a needle attached to the carbon-based material.

9. The device of claim 1, further comprising:
a layer located at least one of adjacent to or underneath the sensing components, the layer includes integrated circuit components being in signal communication with the sensing components.

10. A method of making a three-axis magnetic sensing device, the method comprising:
forming first and second sensing components on a surface of a substrate, the first and second sensing components configured to sense magnetic fields along two orthogonal axes planar to the surface of the substrate; and
forming a third sensing component on the substrate, the third sensing component configured to sense a magnetic field along an axis out of plane of the surface of the substrate,
wherein the third sensing component includes a carbon-based material.

11. The method of claim 10, wherein the first and second sensing components comprise anisotropic magnetoresistive sensors.

12. The method of claim 11, wherein the carbon-based material comprises carbon nanotubes.

13. The method of claim 12, wherein forming the third sensing component comprises attaching a needle to the carbon-based material.

14. The method of claim 13, wherein the needle comprises ferromagnetic material.

15. The method of claim 13, wherein forming the third sensing component comprises forming at least two electrodes on the surface, wherein the at least two electrodes make contact with the carbon-based material.

16. The method of claim 10, wherein the carbon-based material comprises carbon nanotubes.

17. The method of claim 10, wherein forming the third sensing component comprises attaching a needle to the carbon-based material.

18. The method of claim 10, further comprising:
forming integrated circuit components into a layer located at least one of adjacent to or underneath the sensing components, wherein the integrated circuit components are in signal communication with the sensing components.
